(19) United States
(12) Patent Application Publication
(10) Pub. No.: US 2026/0081515 A1
(43) Pub. Date: Mar. 19, 2026

(54) ZERO-CROSSING DETECTION CIRCUIT

(71) Applicant: SHANGHAI XINLONG SEMICONDUCTOR TECHNOLOGY CO., LTD., Pudong New Area, Shanghai (CN)

(72) Inventors: Ruiping LI, Shanghai (CN); Jinlong XU, Shanghai (CN)

(73) Assignee: SHANGHAI XINLONG SEMICONDUCTOR TECHNOLOGY CO., LTD., Pudong New Area, Shanghai (CN)

(21) Appl. No.: 19/102,498

(22) PCT Filed: Oct. 13, 2023
(86) PCT No.: PCT/CN2023/124413

§ 371 Date: Feb. 10, 2025

(30) Foreign Application Priority Data
Nov. 9, 2022 (CN) 202211394961.6

(51) Int. Cl. H02M 1/08; G01R 19/175; H02M 3/158

(52) U.S. Cl. CPC H02M 1/083; H02M 3/1588; G01R 19/175

(57) ABSTRACT

A zero-crossing detection circuit includes a detection module (1), a short pulse generation module (2) and an output signal processing module (3). The detection module (1) is configured to produce, when a voltage at a detection point rises to a predetermined voltage, a falling edge for triggering a zero-crossing. The short pulse generation module (2) is configured to output, when receiving the falling edge, a high-level pulse signal with a predetermined pulse width. The output signal processing module (3) is configured to perform an operation based on an operating-state signal indicating an operating state of an upper transistor (301), an output signal of the detection module (1) and an output signal of the short pulse generation module (2). When it is determined from the operating-state signal that the upper transistor (301) is OFF, and when the high-level pulse signal is received, the output signal processing module (3) outputs a control signal for turning off a lower transistor (302). With this arrangement, zero-crossing detection can be achieved, which provides more accurate control information to a downstream control module or algorithm, overcoming the problem of low efficiency or difficult startup with conventional systems.

### TECHNICAL FIELD

The present invention relates to the field of integrated circuits and, in particular, to a zero-crossing detection circuit for a switched-mode power supply.

### BACKGROUND

In normal operation of a buck synchronous rectifier circuit, a current flows through a lower transistor (a power transistor connected between a switch pin and a ground for current freewheeling in an inductor) from the ground to the switch pin (often referred to the SW pin). When the system operates in a light load condition, after the lower transistor completes the freewheeling, a capacitor at an output terminal forms a loop, together with the inductor and the lower transistor, for charging the inductor. In this condition, the current through the lower transistor is reversed, i.e., it instead flows from the switch pin to the ground. In this process, the current through the lower transistor will drop to zero at a certain point of time and then reverse (direction). For operation of the buck synchronous rectifier circuit, it is important to detect the zero-crossing point, i.e., the so-called zero-crossing detection, because it can provide a basis for turning off the lower transistor by a downstream stage.

With an upper transistor (a power transistor connected between an input terminal of the system and the switch pin) being OFF, as the lower transistor is freewheeling, the current through the lower transistor flows from the ground to the switch pin. In this condition, a voltage at the SW pin is lower than 0 V. As the current through the lower transistor decreases, the voltage at the SW pin rises and approaches 0 V. However, taking a propagation delay into account, instead of the time when the voltage at the SW pin is detected to reach 0 V (i.e., the time when the current through the lower transistor becomes zero), the time when it rises to a value slightly lower than 0 V (e.g., −30 mV) is usually taken as the zero-crossing point.

For the buck synchronous rectifier circuit, the absence of zero-crossing detection or a circuit for turning off the lower transistor at the zero-crossing point means that the current through the inductor may reverse in some light load conditions. This is equivalent to the output capacitor charging the inductor in these conditions, which would cause unnecessary energy consumption and degrade the system's efficiency.

Further, in some conditions (e.g., heavy load conditions with large duty cycles), a circuit without zero-crossing detection may encounter difficulties in startup.

Therefore, the conventional systems are associated with the problem of low efficiency or difficult startup.

### SUMMARY

It is an objective of the present invention to provide a zero-crossing detection circuit, which overcomes the problem of low efficiency or difficult startup with the conventional systems.

To this end, the present invention provides a zero-crossing detection circuit for use in a buck synchronous rectifier circuit including an upper transistor, a lower transistor, an energy-storage inductor and a detection point. The detection point is configured as a node, to which the upper transistor, the lower transistor and the energy-storage inductor are connected. The zero-crossing detection circuit includes a detection module, a short pulse generation module and an output signal processing module.

The detection module is configured to produce, when a voltage at the detection point rises to a predetermined voltage, a falling edge for triggering a zero-crossing. An absolute difference between the predetermined voltage and 0 V does not exceed 100 mV. The short pulse generation module is configured to output, when receiving the falling edge, a high-level pulse signal with a predetermined pulse width. The output signal processing module is configured to: perform an operation based on an operating-state signal indicating an operating state of the upper transistor, an output signal of the detection module and an output signal of the short pulse generation module; and when it is determined from the operating-state signal that the upper transistor is OFF, and when receiving the high-level pulse signal, output a control signal for turning off the lower transistor.

Optionally, the detection module may include a voltage detection unit configured to change a voltage waveform at its own output terminal when the voltage at the detection point rises to the predetermined voltage,
the voltage detection unit including a current mirror, a first triode, a second triode, a resistor and a first NMOS transistor, the current mirror including one input terminal and two output terminals, the input terminal of the current mirror configured to receive a bias current, the two output terminals of the current mirror having the same current-output ratio, both the first and second triodes being NPN-type triodes, one of the two output terminals of the current mirror connected to a collector of the first triode, the other of the two output terminals of the current mirror connected to a collector of the second triode, a base of the first triode connected to a base of the second triode, the collector of the first triode connected to the base thereof, an emitter of the second triode configured for grounding, an emitter of the first triode connected to one end of the resistor, the other end of the resistor connected to a source of the first NMOS transistor, a drain of the first NMOS transistor configured for connection with the detection point, a gate of the first NMOS transistor configured for connection with a power supply, the collector of the second triode configured as an output terminal of the voltage detection unit.

Optionally, electrical parameters of the voltage detection unit may satisfy −(I1*m*R1+V_{T}*ln(n))=Vm, where Vm is the predetermined voltage, I1 is the bias current, m is the current-output ratio of the two output terminals of the current mirror, n is an emitter area ratio of the second triode to the first triode, R1 is the resistance of the resistor, and V_{T} is a thermal voltage.

Optionally, the detection module may further include a falling edge sharpener unit configured to increase a slope of the falling edge of the output signal from the voltage detection unit,
the falling edge sharpener unit including a first inverter and a second inverter, an input terminal of the first inverter connected to the output terminal of the voltage detection unit, an output terminal of the first inverter connected to an input terminal of the second inverter, an output terminal of the second inverter configured as an output terminal, from which the falling edge for triggering the zero-crossing is output.

Optionally, the predetermined pulse width may be less than 200 ns.

Optionally, the short pulse generation module may include a first PMOS transistor, a second PMOS transistor, a third PMOS transistor, a second NMOS transistor, a third NMOS transistor, a fourth NMOS transistor and a first NOR gate,
a source of the first PMOS transistor configured for connection with a power supply, a drain of the first PMOS transistor connected to a drain of the second NMOS transistor, a source of the second NMOS transistor configured for grounding, a gate of the first PMOS transistor connected to a gate of the second NMOS transistor and to an output terminal, from which the falling edge for triggering the zero-crossing is output,
a source of the second PMOS transistor configured for connection with the power supply, a drain of the second PMOS transistor connected to a drain of the third NMOS transistor, a source of the third NMOS transistor configured for grounding, a gate of the second PMOS transistor connected to a gate of the third NMOS transistor and to the drain of the first PMOS transistor,
a source of the third PMOS transistor configured for connection with the power supply, a drain of the third PMOS transistor connected to a drain of the fourth NMOS transistor, a source of the fourth NMOS transistor configured for grounding, a gate of the third PMOS transistor connected to a gate of the fourth NMOS transistor and to the drain of the second PMOS transistor,
an input terminal of the first NOR gate connected to the drain of the third PMOS transistor, another input terminal of the first NOR gate connected to the output terminal, from which the falling edge for triggering the zero-crossing is output.

Optionally, the zero-crossing detection circuit may include at least one of: a ratio of a channel length of the first PMOS transistor to a channel width of the first PMOS transistor, which is greater than 10; the product of a channel length of the third NMOS transistor and a channel width of the third NMOS transistor, which lies between 50 μm² and 500 μm²; and the channel length of the third PMOS transistor, as well as a channel length of the fourth NMOS transistor, which is selected as a minimum value permitted by a manufacturing process used.

Optionally, the output signal processing module may also be configured to output, when it is determined from the operating-state signal that the upper transistor is ON, the control signal for turning off the lower transistor.

Optionally, the output signal processing module may include a second NOR gate, a third NOR gate and a fourth NOR gate,
an input terminal of the second NOR gate connected to an output terminal of the short pulse generation module, another input terminal of the second NOR gate connected to an output terminal of the third NOR gate,
an input terminal of the third NOR gate connected to an output terminal of the second NOR gate, another input terminal of the third NOR gate configured to receive the operating-state signal, wherein the operating-state signal indicates, when at a high level, that the upper transistor is ON,
the output terminal of the third NOR gate also connected to an input terminal of the fourth NOR gate, another input terminal of the fourth NOR gate connected to the output terminal of the first inverter,
wherein a signal is output from the fourth NOR gate as an output signal of the zero-crossing detection circuit, or an output signal of the fourth NOR gate is inverted to form the output signal of the zero-crossing detection circuit.

Optionally, the operating-state signal may be a drive signal for the upper transistor.

Compared with the prior art, the present invention provides a zero-crossing detection circuit including a detection module, a short pulse generation module and an output signal processing module. The detection module is configured to produce, when a voltage at a detection point rises to a predetermined voltage, a falling edge for triggering a zero-crossing. The short pulse generation module is configured to output, when receiving the falling edge, a high-level pulse signal with a predetermined pulse width. The output signal processing module is configured to perform an operation based on an operating-state signal indicating an operating state of an upper transistor, an output signal of the detection module and an output signal of the short pulse generation module. When it is determined from the operating-state signal that the upper transistor is OFF, and when the high-level pulse signal is received, the output signal processing module outputs a control signal for turning off a lower transistor. With this arrangement, zero-crossing detection can be achieved, which provides more accurate control information to a downstream control module or algorithm, overcoming the problem of low efficiency or difficult startup with conventional systems.

### BRIEF DESCRIPTION OF THE DRAWINGS

Those of ordinary skill in the art will understand that the following drawings are presented to enable a better understanding of the present invention and not intended to limit the scope thereof in any sense, in which:

FIG. 1 is a schematic diagram showing the structure of a buck synchronous rectifier circuit according to an embodiment of present invention;

FIG. 2 is a schematic diagram showing wiring of a zero-crossing detection circuit according to an embodiment of present invention;

FIG. 3 schematically illustrates waveforms at key measurement points in a detection module according to an embodiment of the present invention;

FIG. 4 schematically illustrates waveforms at key measurement points in a short pulse generation module according to an embodiment of the present invention; and

FIG. 5 schematically illustrates waveforms at key measurement points in an output signal processing module according to an embodiment of the present invention.

### LIST OF REFERENCE NUMERALS

1 detection module; 2 short pulse generation module; 3 output signal processing module; 11 voltage detection unit; 12 falling edge sharpener unit; 13 current mirror;
10 power supply circuit; 20 drive circuit; 30 external power transistor; 40 output circuit; 301 upper transistor; 302 lower transistor; 401 energy-storage inductor; 402 output filter capacitor; 403 load; 101 input power supply module; 102 input filter capacitor; 103 external energy-storage capacitor.

### DETAILED DESCRIPTION

Objectives, advantages and features of the present invention will become more apparent upon reading the following more detailed description with reference to the accompanying drawings, which illustrate particular embodiments thereof. Note that the figures are provided in a very simplified form not necessarily drawn to exact scale for the only purpose of helping to explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents. The term “or” is generally employed in the sense of “and/or”, “several” of “at least one” and “at least two” of “two or more”. In addition, the terms “first”, “second” and “third” are intended only for illustration and are not to be construed as denoting or implying relative importance, or as implicitly indicating the numerical number of the referenced items. Accordingly, defining an item with “first”, “second” or “third” is an explicit or implicit indication of the presence of one or at least two such items. The terms “one end” and “the other end”, as well as “proximal end” and “distal end”, are used to generally refer to opposing ends including the opposing endpoints, rather than only to the endpoints. As used herein, the terms “mounting”, “coupling”, “connecting” and any variants thereof should be interpreted in a broad sense. For instance, a connection may be a permanent, detachable or integral connection, or a mechanical or electrical connection, or a direct or indirect connection with one or more intervening media, or an internal communication or interaction between two elements. When an element is referred herein to as being “disposed on” another element, this is generally intended to only mean that there is a connection, coupling, engagement or transmission between the two elements, which may be either direct or indirect with one or more intervening elements, and should not be interpreted as indicating or implying a particular spatial position relationship between the two elements, i.e., the element may be located inside, outside, above, under, beside, or at any other location relative to the other element, unless the context clearly dictates otherwise. Those of ordinary skill in the art can understand the specific meanings of the above-mentioned terms herein, depending on their context.

In principle, the present invention seeks to provide a zero-crossing detection circuit, which addresses the need of the prior art for a zero-crossing detection circuit capable of providing more accurate control information to a control module or algorithm.

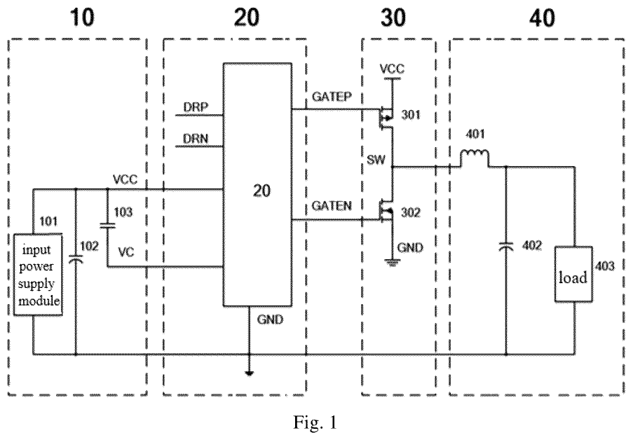

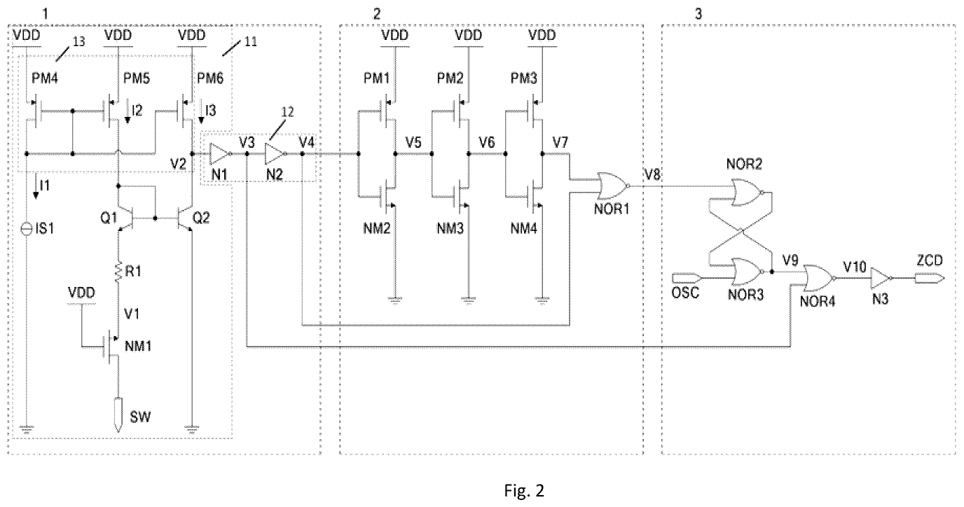

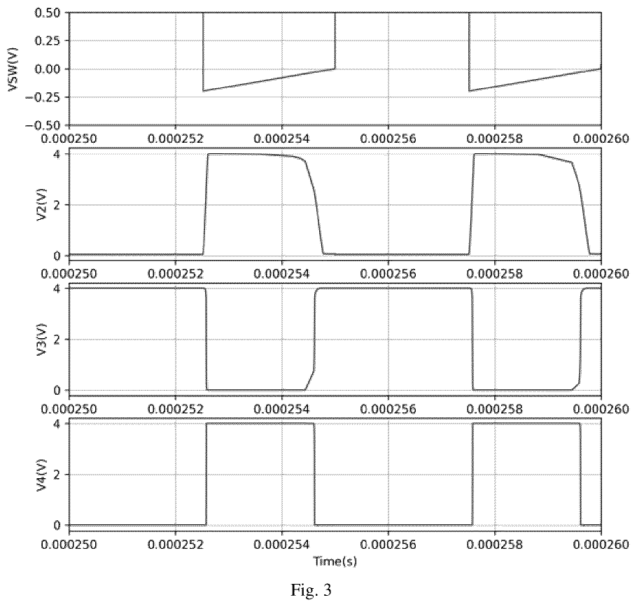

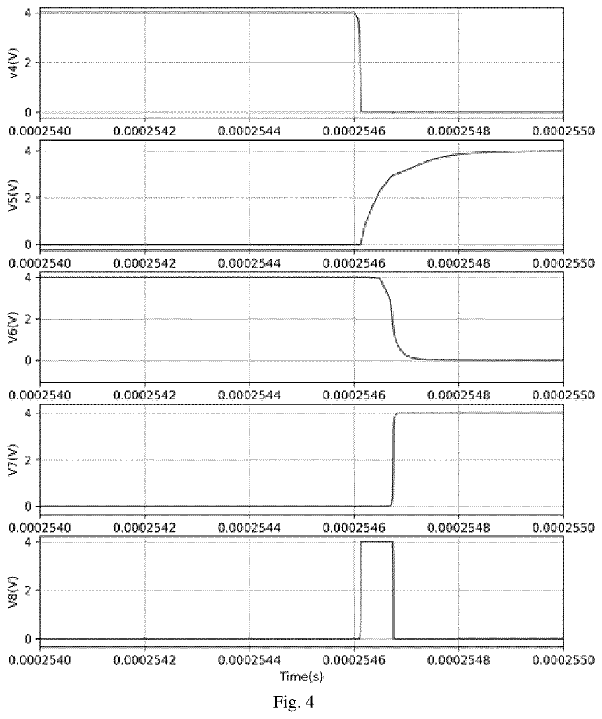

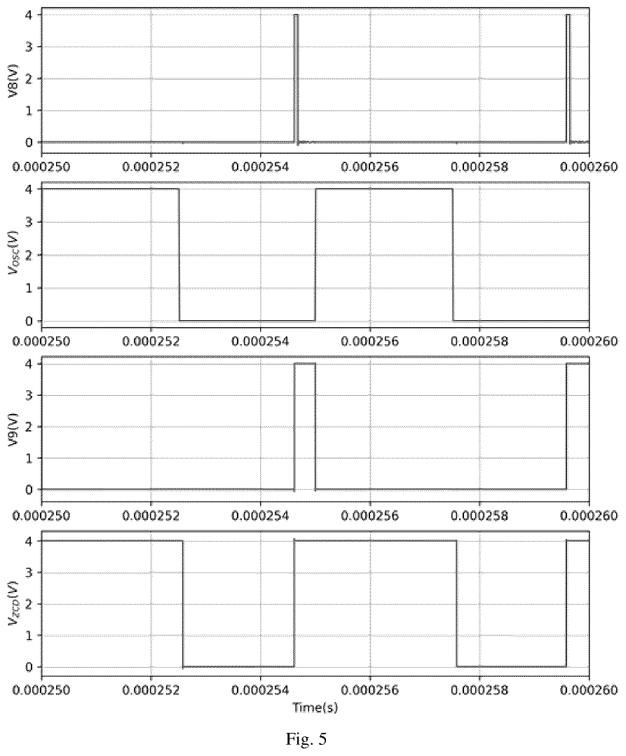

The present invention will be described below with reference to the accompanying FIGS. 1-5, in which FIG. 1 is a schematic diagram showing the structure of a buck synchronous rectifier circuit according to an embodiment of present invention; FIG. 2 is a schematic diagram showing wiring of a zero-crossing detection circuit according to an embodiment of present invention; FIG. 3 schematically illustrates waveforms at key measurement points in a detection module according to an embodiment of the present invention; FIG. 4 schematically illustrates waveforms at key measurement points in a short pulse generation module according to an embodiment of the present invention; and FIG. 5 schematically illustrates waveforms at key measurement points in an output signal processing module according to an embodiment of the present invention.

In one embodiment of the present invention, there is provided a zero-crossing detection circuit for use in a buck synchronous rectifier circuit. The buck synchronous rectifier circuit can be understood with reference to FIG. 1. The buck synchronous rectifier circuit includes a power supply circuit 10, a drive circuit 20, external power transistors 30 and an output circuit 40. The external power transistors 30 include an upper transistor 301 and a lower transistor 302. In the figure, DRP denotes a control signal for a PMOS power transistor (serving as the upper transistor 301); GATEP denotes a drive signal for the upper transistor 301; DRN denotes a control signal for an NMOS power transistor (the lower transistor 302); and GATEN denotes a drive signal for the lower transistor 302. The upper transistor 301 (i.e., the PMOS power transistor) is a power output transistor for the entire system, and the lower transistor 302 (i.e., the NMOS power transistor) serves to provide a freewheeling loop for an energy-storage inductor 401 in turn-off cycles of the PMOS power transistor in the drive circuit 20. In the figure, 401 denotes the energy-storage inductor; 402 denotes an output filter capacitor; 403 denotes a load; 101 denotes an input power supply module for providing an external power supply; 102 denotes an input filter capacitor; and 103 denotes an external energy-storage capacitor. The operating principles of the buck synchronous rectifier circuit have been described above in the Background section and are not repeated here.

The node where the upper transistor 301, the lower transistor 302 and the energy-storage inductor 401 are connected, is configured as a detection point SW.

Although the zero-crossing detection circuit is not shown in FIG. 1, it will be understood that an input terminal (or one of input terminals) of the zero-crossing detection circuit is connected to the detection point SW. The wiring of the buck synchronous rectifier circuit shown in FIG. 1 is merely one possible example, and the zero-crossing detection circuit may otherwise work with the buck synchronous rectifier circuit.

As noted above, the buck synchronous rectifier circuit includes the upper transistor 301, the lower transistor 302, the energy-storage inductor 401 and the detection point SW. The node, where the upper transistor 301, the lower transistor 302 and the energy-storage inductor 401 are connected, is configured as the detection point SW.

Referring to FIG. 2, the zero-crossing detection circuit includes a detection module 1, a short pulse generation module 2 and an output signal processing module 3.

The detection module 1 is configured to produce, when a voltage at the detection point SW rises to a predetermined voltage, a falling edge for triggering a zero-crossing. The short pulse generation module 2 is configured to output, when detecting the falling edge, a high-level pulse signal with a predetermined pulse width. The output signal processing module 3 is configured to perform an operation based on an operating-state signal OSC indicating an operating state of the upper transistor 301, an output signal from the detection module 1 and an output signal from the short pulse generation module 2. When it is determined from the operating-state signal that the upper transistor 301 is OFF, and when the high-level pulse signal is received, the output signal processing module 3 outputs a control signal for turning off the lower transistor 302.

The predetermined voltage is a value serving as a basis for determining whether the detection point is to experience a zero-crossing. In practice, it is usually set to −30 mV. Thus, the absolute difference between the predetermined voltage and 0 V does not exceed 100 mV. The predetermined pulse width is relatively small. In the present embodiment, it is less than 200 ns. The operating-state signal OSC is indicative of whether the upper transistor 301 is currently ON or OFF. It may be arbitrarily configured, as long as it can indicate the operating state of the upper transistor 301. For example, it may be selected as a signal in relation to the driving of the upper transistor 301.

With continued reference to FIG. 2, the detection module 1 includes a voltage detection unit 11. The voltage detection unit 11 is configured to, upon the voltage at the detection point SW rising to the predetermined voltage, make a change in a voltage waveform at its own output terminal.

The voltage detection unit 11 includes a current mirror 13, a first triode Q1, a second triode Q2, a resistor R1 and a first NMOS transistor NM1. The current mirror 13 has one input terminal and two output terminals. The input terminal of the current mirror is configured to receive a bias current I1. In the present embodiment, the bias current I1 is provided by a constant current source IS1. The two output terminals of the current mirror have the same current-output ratio. In other words, the currents I2 and I3 from the two output terminals of the current mirror are equal. The first triode Q1 and the second triode Q2 are both NPN-type triodes. One of the output terminals of the current mirror is connected to a collector of the first triode Q1, and the other of the output terminals of the current mirror is connected to a collector of the second triode Q2. A base of the first triode Q1 is connected to a base of the second triode Q2. The collector of the first triode Q1 is connected to its own base, and an emitter of the second triode Q2 is configured for grounding. An emitter of the first triode Q1 is connected to one end of the resistor R1, and the other end of the resistor R1 is connected to a source of the first NMOS transistor NM1. A drain of the first NMOS transistor NM1 is configured for connection with the detection point, and a gate of the first NMOS transistor NM1 is configured for connection with a power supply VDD. The collector of the second triode Q2 is configured as an output terminal of the voltage detection unit 11.

In the embodiment of FIG. 2, the current mirror 13 is composed of three low-voltage PMOS transistors of the same type, which are labeled respectively as PM4, PM5 and PM6 and have a PM4:PM5:PM6 ratio of 1:m:m. A drain of PM4 provides the input terminal of the current mirror, while drains of PM5 and PM6 serve as the output terminals of the current mirror. A current through PM1 is equal to that through IS1, and both are denoted as I1. Currents through PM2 and PM3 are respectively I2 and I3. Ideally (i.e., when the second triode Q2 is not cut off),

$$I 3 = I 2 = I 1 * m .$$

An emitter area ratio of the first triode Q1 to the second triode Q2 is 1:n. If base currents in the first triode Q1 and the second triode Q2 are ignored, then both the first triode Q1 and the second triode Q2 operate in the active region. Thus, currents through the first triode Q1 and the second triode Q2 are I2 and I3, and I2=I3. Accordingly, the difference ΔV_{BE} between V_{BE} (base-to-emitter voltage drop) values of the first triode Q1 and the second triode Q2 can be obtained as:

$$Δ {V}_{BE} = {V}_{BEQ 1} - {V}_{BEQ 2} = {V}_{T} * ln ( n ) ,$$

where V_{T} represents the thermal voltage, which is about 26 mV at room temperature. If n=2, then

$$Δ {V}_{BE} \approx 18 mV .$$

Additionally, a current through the resistor R1 is I2, and a voltage drop V_{R1} across its ends is:

$${V}_{R 1} = I 2 * R 1 = I 1 * m * R 1.$$

The first NMOS transistor NM1 is a symmetric high-voltage NMOS. When the voltage at SW is high (i.e., when the upper transistor is ON, which is typically equal to the system's maximum permissible input voltage), a source voltage V1 of the first NMOS transistor NM1 is

$$V 1 = VDD - {V}_{GS 1} ,$$

where V_{GS1} (a drive voltage for the first NMOS transistor NM1) is typically lower than 1 V. In this process, NM1 is configured for high-voltage isolation for ensuring that the rest of the system can operate at a normal voltage.

When the voltage at SW is low (i.e., when the upper transistor 301 is OFF, which is typically lower than 0 V), since the VDD voltage is typically much higher than a turn-on threshold voltage of the first NMOS transistor NM1, the first NMOS transistor NM1 is turned on. If its on-resistance is ignored, then V1 is equal to VSW, where VSW represents the voltage at SW.

When the voltage VSW at SW is lower than −(V_{R1}+ΔV_{BE}), a voltage V2 at the output terminal of the voltage detection unit 11 is at a high level. When the voltage VSW at SW is higher than −(V_{R1}+ΔV_{BE}), V2 is at a low level. That is, the voltage detection unit 11 changes the voltage waveform at its output terminal. Thus, −(V_{R1}+ΔV_{BE}) can be regarded as a criterion for the zero-crossing detection circuit to determine a zero-crossing event, i.e., as the aforementioned predetermined voltage. As can be seen, this voltage is determined by both the ratio of the first triode Q1 to the second triode Q2 and the voltage drop across the ends of the resistor R1. With this arrangement, the determination criterion can be readily adjusted by a circuit designer.

From the above analysis, it can be concluded that the criterion is met if the electrical parameters of the voltage detection unit satisfy −(I1*m*R1+V_{T}*ln(n))=Vm, where Vm is the predetermined voltage, I1 is the bias current, m is the current-output ratio of the two output terminals of the current mirror, n is the emitter area ratio of the second triode to the first triode, R1 is the resistance of the resistor, and V_{T} is the thermal voltage.

Since the voltage V2 ramps slowly, two inverters N1 and N2 may be added to speed up its ramping rate. The inverter N1 can appropriately adjust an inversion voltage at its input terminal to provide the performance of this circuit. That is, the detection module 1 further includes a falling edge sharpener unit 12. The falling edge sharpener unit 12 is configured for increasing the slope of a falling edge of the output signal from the voltage detection unit 11. Here, by “increasing”, it is intended to mean that the absolution value of the slope is to be increased. When the waveform of the falling edge is not linear, the slope is to be understood as an equivalent slope of the falling edge, which is defined, for example, as the amplitude change of the falling edge divided by its total time duration.

The falling edge sharpener unit 12 includes the first inverter N1 and the second inverter N2. The input terminal of the first inverter N1 is connected to the output terminal of the voltage detection unit 11, and an output terminal of the first inverter N1 is connected to an input terminal of the second inverter N2. An output terminal of the second inverter N2 is configured to output a falling edge for triggering a zero-crossing. In other embodiments, the falling edge sharpener unit 12 may be otherwise structures according to different operating principles.

Reference is made to FIG. 3, which schematically illustrates waveforms at key measurement points in the detection module in a typical operating condition.

As can be seen from the figure, when the voltage VSW rises to about −30 mV, a relatively slow falling edge is generated at V2, which is then inverted by the first inverter N1 so that the inverted version V3 present at the output terminal thereof transitions at a significantly increased rate. It is then again inverted by the second inverter N2 so that the inverted version V4 at the output terminal thereof ramps at an additionally increased rate. In this way, the slow falling edge of the voltage V2 is successfully sharpened, as designed, by the two inverter stages.

The falling edge of V4 occurs just at the time when VSW reaches −30 mV.

The output signal of the detection module 1 is not suitable to be directly used to drive the lower transistor 302 (because such direct use may otherwise cause fluctuations in the circuit), such that the output signal of the detection module 1 needs to be further processed into a short pulse signal, typically, the short pulse signal has a pulse width less than 200 ns, i.e., the aforementioned predetermined pulse width is less than 200 ns.

Specifically, the short pulse generation module 2 may include a first PMOS transistor PM1, a second PMOS transistor PM2, a third PMOS transistor PM3, a second NMOS transistor NM2, a third NMOS transistor NM3, a fourth NMOS transistor NM4 and a first NOR gate NOR1.

A source of the first PMOS transistor PM1 is configured for connection with the power supply VDD, and a drain of the first PMOS transistor PM1 is connected to a drain of the second NMOS transistor NM2. A source of the second NMOS transistor NM2 is configured for grounding, and a gate of the first PMOS transistor PM1 is connected to a gate of the second NMOS transistor NM2 and to the output terminal, from which a falling edge for triggering a zero-crossing is output (i.e., the output terminal of the second inverter N2).

A source of the second PMOS transistor PM2 is configured for connection with the power supply VDD, and a drain of the second PMOS transistor PM2 is connected to a drain of the third NMOS transistor NM3. A source of the third NMOS transistor NM3 is configured for grounding, and a gate of the second PMOS transistor PM2 is connected to a gate of the third NMOS transistor NM3 and to the drain of the first PMOS transistor PM1.

A source of the third PMOS transistor PM3 is configured for connection with the power supply VDD, and a drain of the third PMOS transistor PM3 is connected to a drain of the fourth NMOS transistor NM4. A source of the fourth NMOS transistor NM4 is configured for grounding, and a gate of the third PMOS transistor PM3 is connected to a gate of the fourth NMOS transistor NM4 and to the drain of the second PMOS transistor PM2.

An input terminal of the first NOR gate NOR1 is connected to the drain of the third PMOS transistor PM3, and another input terminal of the first NOR gate NOR1 is connected to the output terminal, from which a falling edge for triggering a zero-crossing is output (i.e., the output terminal of the second inverter N2).

In order for improved output performance to be achieved, the circuit is in principle designed so that a channel length of the first PMOS transistor PM1 is much greater than a channel width thereof, in order to reduce a current through PM1. Typically, a ratio of the two is greater than 10, and is typically 20.

In order to maximize the Cos capacitance, it is desired that the product of a channel length of the third NMOS transistor NM3 and a channel width thereof is as large as possible. Meanwhile, W is desired to be relatively small, in order to enable an inverter made of PM2 and NM3 to have an increased inversion voltage. Generally, the product of the two lies between 50 μm² and 500 μm². The channel length of the third NMOS transistor NM3 is typically 20 μm, and the channel width of the third NMOS transistor NM3 is typically 4 μm.

Desirably, the channel length of the third PMOS transistor PM3 is selected as a minimum value permitted by the manufacturing process used. Additionally, a channel length of the fourth NMOS transistor NM4 is also selected as a minimum value permitted by the manufacturing process used. This helps reduce parasitic capacitance and accelerate response.

In various embodiments, all or some of the design principles described above may be complied with.

PM4 may be referred to as a fourth PMOS transistor, PM5 as a fifth PMOS transistor and PM6 as a sixth PMOS transistor, in order to distinguish them from one another.

Reference is made to FIG. 4, which schematically illustrates waveforms at key measurement points in the short pulse generation module in a typical operating condition. In the figure, V5 denotes a voltage at the drain of the first PMOS transistor PM1; V6, a voltage at the drain of the second PMOS transistor PM2; V7, a voltage at the drain of the third PMOS transistor PM3; and V8, a voltage at an output terminal of the first NOR gate NOR1.

As can be seen from the figure, under the action of PM1 and NM3, the voltage V5 ramps up very slowly, and V8 is eventually produced as a short voltage pulse from this slowly ramping voltage. In the example of FIG. 4, it has a pulse width of about 60 ns. The pulse width of the short voltage pulse V8 can be adjusted by changing the sizes of PM1 and NM3.

The short pulse V8 is configured to provide a signal to a set-reset (SR) flip-flop in the output signal processing module 3. Direct use of the output signal V4 of the detection module 1 without processing it by the short pulse generation module 2 would cause fluctuations in the voltage V_{GS} due to absence of latching.

The operating-state signal OSC is an external signal, the operating-state signal OSC is required to decrease, when the upper transistor 301 is turned off, starting detection of the voltage at SW for the current period. The operating-state signal OSC is also required to increase, when the upper transistor is turned on, ending the detection of the voltage at SW for the current period. In the present embodiment, the operating-state signal OSC is a drive signal for the upper transistor. In alternative embodiments, it may be selected as a control signal related to the driving of the upper transistor, or configured as a feedback signal indicating the operating state of the upper transistor according to an operating parameter of the circuit (e.g., a voltage, current or the like at a specified location therein).

In order to facilitate making of logical determinations by a downstream control module or algorithm, the output signal processing module 3 may also be configured to output a control signal for turning off the lower transistor when it is determined from the operating-state signal that the upper transistor is ON. Alternatively, the zero-crossing detection circuit may do nothing with the logic in the period when the upper transistor is ON, and such processing logic may be provided by a different logic module.

In one embodiment, the output signal processing module 3 includes a second NOR gate NOR2, a third NOR gate NOR3, a fourth NOR gate NOR4 and a third inverter N3.

An input terminal of the second NOR gate NOR2 is connected to an output terminal of the short pulse generation module 2, and another input terminal of the second NOR gate NOR2 is connected to an output terminal of the third NOR gate NOR3.

An input terminal of the third NOR gate NOR3 is connected to an output terminal of the second NOR gate NOR2, and another input terminal of the third NOR gate NOR3 is configured to receive the operating-state signal OSC. When at a high level, the operating-state signal OSC indicates that the upper transistor 301 is being ON.

An output terminal of the third NOR gate NOR3 is connected to an input terminal of the fourth NOR gate NOR4, and another input terminal of the fourth NOR gate NOR4 is connected to the output terminal of the first inverter N1.

An input terminal of the third inverter N3 is connected to an output terminal of the fourth NOR gate NOR4, and an output terminal of the third inverter N3 is configured as an output terminal of the output signal processing module 3.

The NOR gates NOR2 and NOR3 constitute the SR flip-flop for providing latching capabilities. A relationship of V8, OSC and V9 (a voltage at the output terminal of the third NOR gate NOR3, as shown in FIG. 2) is shown in Table 1, in which “1” denotes a high level, and “0” represents a low level.

TABLE 1
Truth Values of V8, V9 and OSC

| V8 | OSC | V9 |
|---|---|---|
| 0 | 0 | Unchanged |
| 0 | 1 | 0 |
| 1 | 0 | 1 |
| 1 | 1 | 0 |

The fourth NOR gate NOR4 may perform a NOR operation on V3 and V9 to produce a signal V10. Additionally, an OR operation may be performed on V3 and V9 essentially to avoid any error in the signal V9 in some cases, improving the system's reliability.

The signal V10 (present at the output terminal of the fourth NOR gate NOR4, as shown in FIG. 2) may be inverted by the inverter N3 into a signal ZCD (V_{ZCD}). N3 is not mandatory, and may be included or not, depending essentially on the control logic of the downstream lower transistor drive circuit. In other words, the output signal of the fourth NOR gate NOR4 may be directly taken as the output signal ZCD of the zero-crossing detection circuit, or inverted and then output as the output signal ZCD of the zero-crossing detection circuit.

Reference is made to FIG. 5, which schematically illustrates waveforms at key measurement points in the output signal processing module in a typical operating condition.

As can be seen from FIG. 5, when V_{OSC} (a voltage of the signal OSC) is at a high level (indicating that the upper transistor 301 is ON), V_{ZCD} is always at a high level. When V_{OSC} is at a low level (indicating that the upper transistor 301 is OFF), V_{ZCD} transitions from a high level to a low level, or from a low level to a high level, in response to a rising edge of V8, which is aligned with a falling edge of V4 occurring at a VSW value of −30 mV. Thus, the output signal of the zero-crossing detection circuit behaves, as expected.

The output signal of the zero-crossing detection circuit may be input to a downstream control module or algorithm to desirably drive the lower transistor 302, resulting in an improvement in the system's efficiency or startup success rate.

The proposed circuit is simple, reliable and suitable for integration into a buck power supply chip for synchronous rectification.

In summary, embodiments of the present invention provide a zero-crossing detection circuit including a detection module, a short pulse generation module and an output signal processing module. The detection module is configured to produce, when a voltage at a detection point rises to a predetermined voltage, a falling edge for triggering a zero-crossing. The short pulse generation module is configured to output, when receiving the falling edge, a high-level pulse signal with a predetermined pulse width. The output signal processing module is configured to perform an operation based on an operating-state signal indicating an operating state of an upper transistor, an output signal of the detection module and an output signal of the short pulse generation module. When it is determined from the operating-state signal that the upper transistor is OFF, and when the high-level pulse signal is received, the output signal processing module outputs a control signal for turning off a lower transistor. With this arrangement, zero-crossing detection can be achieved, which provides more accurate control information to a downstream control module or algorithm, overcoming the problem of low efficiency or difficult startup with conventional systems.

The description presented above is merely that of a few preferred embodiments of the present invention and does not limit the scope thereof in any sense. Any and all changes and modifications made by those of ordinary skill in the art based on the above teachings fall within the scope as defined in the appended claims.

1. A zero-crossing detection circuit, being used in a buck synchronous rectifier circuit, the buck synchronous rectifier circuit comprising an upper transistor, a lower transistor, an energy-storage inductor and a detection point, a connection node between the upper transistor, the lower transistor and the energy-storage inductor configured as the detection point, the zero-crossing detection circuit comprising a detection module, a short pulse generation module and an output signal processing module,
the detection module configured to produce, when a voltage at the detection point rises to a predetermined voltage, a falling edge for triggering a zero-crossing, wherein an absolute difference between the predetermined voltage and 0 V does not exceed 100 mV,
the short pulse generation module configured to output, when receiving the falling edge, a high-level pulse signal with a predetermined pulse width,
the output signal processing module configured to perform an operation based on an operating-state signal indicating an operating state of the upper transistor, an output signal of the detection module and an output signal of the short pulse generation module; and when it is determined from the operating-state signal that the upper transistor is in an off state, and when receiving the high-level pulse signal, the output signal processing module configured to output a control signal for turning off the lower transistor.

2. The zero-crossing detection circuit according to claim 1, wherein the detection module comprises a voltage detection unit, the voltage detection unit configured to change a voltage waveform at an output terminal of the voltage detection unit when the voltage at the detection point rises to the predetermined voltage,
the voltage detection unit comprising a current mirror, a first triode, a second triode, a resistor and a first NMOS transistor,
the current mirror comprising one input terminal and two output terminals, the input terminal of the current mirror configured to receive a bias current, the two output terminals of the current mirror having the same current-output ratio,
both the first triode and the second triode being NPN-type triodes, one of the two output terminals of the current mirror connected to a collector of the first triode, the other of the two output terminals of the current mirror connected to a collector of the second triode, a base of the first triode connected to a base of the second triode, the collector of the first triode connected to the base of the first triode, an emitter of the second triode configured for grounding,
an emitter of the first triode connected to one end of the resistor, the other end of the resistor connected to a source of the first NMOS transistor, a drain of the first NMOS transistor configured for connection with the detection point, a gate of the first NMOS transistor configured for connection with a power supply,
the collector of the second triode configured as the output terminal of the voltage detection unit.

3. The zero-crossing detection circuit according to claim 2, wherein electrical parameters of the voltage detection unit satisfy −(I1*m*R1+V_{T}*ln(n))=Vm, where Vm is the predetermined voltage, I1 is the bias current, m is the current-output ratio of the two output terminals of the current mirror, n is an emitter area ratio of the second triode to the first triode, R1 is the resistance of the resistor, and V_{T} is a thermal voltage.

4. The zero-crossing detection circuit according to claim 2, wherein the detection module further comprises a falling edge sharpener unit, the falling edge sharpener unit configured to increase a slope of the falling edge of the output signal from the voltage detection unit,
the falling edge sharpener unit comprising a first inverter and a second inverter, an input terminal of the first inverter connected to the output terminal of the voltage detection unit, an output terminal of the first inverter connected to an input terminal of the second inverter, an output terminal of the second inverter configured as an output terminal, from which the falling edge for triggering the zero-crossing is output.

5. The zero-crossing detection circuit according to claim 1, wherein the predetermined pulse width is less than 200 ns.

6. The zero-crossing detection circuit according to claim 1, wherein the short pulse generation module comprises a first PMOS transistor, a second PMOS transistor, a third PMOS transistor, a second NMOS transistor, a third NMOS transistor, a fourth NMOS transistor and a first NOR gate,
a source of the first PMOS transistor configured for connection with a power supply, a drain of the first PMOS transistor connected to a drain of the second NMOS transistor, a source of the second NMOS transistor configured for grounding, a gate of the first PMOS transistor connected to a gate of the second NMOS transistor, and the gate of the first PMOS transistor connected to an output terminal, from which the falling edge for triggering the zero-crossing is output,
a source of the second PMOS transistor configured for connection with the power supply, a drain of the second PMOS transistor connected to a drain of the third NMOS transistor, a source of the third NMOS transistor configured for grounding, a gate of the second PMOS transistor connected to a gate of the third NMOS transistor, and the gate of the second PMOS transistor connected to the drain of the first PMOS transistor,
a source of the third PMOS transistor configured for connection with the power supply, a drain of the third PMOS transistor connected to a drain of the fourth NMOS transistor, a source of the fourth NMOS transistor configured for grounding, a gate of the third PMOS transistor connected to a gate of the fourth NMOS transistor, and the gate of the third PMOS transistor connected to the drain of the second PMOS transistor,
an input terminal of the first NOR gate connected to the drain of the third PMOS transistor, another input terminal of the first NOR gate connected to the output terminal, from which the falling edge for triggering the zero-crossing is output.

7. The zero-crossing detection circuit according to claim 6, comprising at least one of:
a ratio of a channel length of the first PMOS transistor to a channel width of the first PMOS transistor, which is greater than 10;
the product of a channel length of the third NMOS transistor and a channel width of the third NMOS transistor, which lies between 50 μm² and 500 μm²; and
a channel length of the third PMOS transistor is selected as a minimum value permitted by a manufacturing process used, and a channel length of the fourth NMOS transistor is selected as a minimum value permitted by a manufacturing process used.

8. The zero-crossing detection circuit according to claim 1, wherein the output signal processing module is also configured to output, when it is determined from the operating-state signal that the upper transistor is in an on state, the control signal for turning off the lower transistor.

9. The zero-crossing detection circuit according to claim 4, wherein the output signal processing module comprises a second NOR gate, a third NOR gate and a fourth NOR gate,
an input terminal of the second NOR gate connected to an output terminal of the short pulse generation module, another input terminal of the second NOR gate connected to an output terminal of the third NOR gate,
an input terminal of the third NOR gate connected to an output terminal of the second NOR gate, another input terminal of the third NOR gate configured to receive the operating-state signal, wherein the operating-state signal indicates, when at a high level, that the upper transistor is in an on state,
the output terminal of the third NOR gate also connected to an input terminal of the fourth NOR gate, another input terminal of the fourth NOR gate connected to the output terminal of the first inverter,
wherein a signal is output from the fourth NOR gate as an output signal of the zero-crossing detection circuit, or an output signal of the fourth NOR gate is inverted to form the output signal of the zero-crossing detection circuit.

10. The zero-crossing detection circuit according to claim 9, wherein the operating-state signal is a drive signal for the upper transistor.

11. The zero-crossing detection circuit according to claim 2, wherein the current mirror consists of three low-voltage PMOS transistors of the same type and having a ratio of 1:m:m.

12. The zero-crossing detection circuit according to claim 9, wherein the output signal processing module further comprises a third inverter, an input terminal of the third inverter connected to an output terminal of the fourth NOR gate, an output terminal of the third inverter configured as an output terminal of the output signal processing module.
